(19) United States
(12) Patent Application Publication
(10) Pub. No.: US 2002/0060327 A1
(43) Pub. Date: May 23, 2002

(54) Metallic bridge structure for hetero-junction bipolar transistor

(76) Inventors: Shi-Ming Chen, Hsin-Hua Chen (TW); Henry Chen, Tainan (TW); Wen-Liang Li, Tainan (TW); Juh-Yuh Su, Tainan (TW)

Correspondence Address: J.C. Patents, Inc., Suite 250, 4 Venture, Irvine, CA, 92618, US

(21) Appl. No.: 09/962,715

(22) Filed: Sep. 24, 2001

(30) Foreign Application Priority Data
Nov. 22, 2000 (TW) 89124757

(51) Int. Cl. H01L 31/0328

(52) U.S. Cl. 257/197

(57) ABSTRACT

A method for forming a metal bridge in a hetero-junction bipolar transistor. The method includes etching away a portion of the semiconductor layers under a metallic layer so that a device region and a contact pad region on the semiconductor substrate are isolated from each other. The invention not only can produce small area hetero-junction bipolar transistors with ease, the invention can also fabricate large area and small area hetero-junction bipolar transistors at the same time. By clearing away contact pad capacitance, hetero-junction bipolar transistors suitable for high frequency applications can be manufactured with a few simple steps. In addition, the metal bridge of this invention can be fabricated on a semiconductor layer, which can serve as a support for increasing the strength of the metal bridge. Furthermore, utilizing the relationship between the intensity of diffraction from a double crystal X-ray diffraction analyzer and the current gain of a hetero-junction bipolar transistor, high performance hetero-junction bipolar transistors can be produced.

### CROSS REFERENCE TO RELATED APPLICATION

This application claims the priority benefit of Taiwan application Ser. No. 89124757, filed Nov. 22, 2000.

### BACKGROUND OF THE INVENTION

1. Field of Invention

The present invention relates to a method of forming a hetero-junction bipolar transistor (HBT). More particularly, the present invention relates to a method of forming a small area hetero-junction bipolar transistor using a simplified metallic bridge process so that important electrical properties can be measured and improved.

2. Description of Related Art

FIGS. 1A through 1D are schematic cross-sectional views showing the progression of steps for producing a conventional large area hetero-junction bipolar transistor. In the production of semiconductor devices, a process for producing a device that requires only low current density DC parameter measurements is generally much simpler. As shown in FIG. 1A, a sub-collector 102, a collector 103, a base 104, an emitter 105 and a cap layer 106 are sequentially formed over a semi-insulating substrate 101 by organo-metallic chemical vapor deposition. A photoresist layer is formed over a portion of the cap layer 106. Using the photoresist layer as a mask, the cap layer 106, the emitter 105, the base 104 and the collector 103 are sequentially etched until the sub-collector 102 is exposed.

As shown in FIG. 1B, lift-off technique is applied to form an emitter metal layer 110 over the cap layer 106 and a collector metal layer 111 over the sub-collector 102. After the formation of the metal layers 110 and 111, an annealing operation is conducted.

As shown in FIG. 1C, the cap layer 106 beside the emitter metal layer 110 is etched to expose a portion of the emitter 105. At this stage, if the emitter 105 is very thick, the emitter 105 must be etched to reduce its thickness. In general, overall thickness of the emitter 105 should be below 700 Å so that the extrinsic emitter 105 can be depleted and short-circuiting between a base metal layer (not shown) and the extrinsic emitter 105 can be prevented.

As shown in FIG. 1D, a patterned photoresist layer is formed over the emitter 105. The emitter 105 exposed by the contact hole is etched to expose the base 104. Lift-off process is again used to form a base metal layer 112. Hence, a thin-out emitter ledge 113 that serves as a passivation layer of the extrinsic base is formed over the base 104. Finally, individual devices are electrically isolated to complete the fabrication of hetero-junction bipolar transistors.

In the aforementioned fabrication process, an emitter having a relatively large surface area is produced. Hence, only low current density DC properties of the hetero-junction bipolar transistor can be measured. Moreover, the emitter needs to have a minimum area of at least 50 μm×50 μm to facilitate contact with a probe pin. In addition, a reliability test of the transistor is difficult to perform because the reliability test needs to be carried out at a higher current density such as 25 KA/cm². If the emitter has an area of about 50 μm×50 μm, a current of about 625 mA is required. The poor heat dissipation of a square emitter together with the current crowding effect may easily lead to device burnout. Consequently, quality of the fabricated epitaxial layer is difficult to determine.

To facilitate reliability testing, the emitter is preferably fabricated into a finger shape such as 2 μm×20 μm. However, with such a small surface area, making contact with the probe pin of a measurement instrument is very difficult. Hence, before conducting any reliability testing, a series of complicated steps are normally conducted to form a larger size contact pad above the emitter. The steps include, for example, forming an insulation layer over the emitter, etching the insulation layer to form a contact hole and depositing metallic material to form a contact pad that connects electrically with the emitter.

FIGS. 2A through 2F are schematic cross-sectional views showing the progression of steps for producing a conventional small area hetero-junction bipolar transistor. As shown in FIG. 2A, a semi-insulating substrate 201 is provided. A sub-collector 202, a collector 203, a base 204, an emitter 205 and a cap layer 206 are sequentially grown over the semi-insulating substrate 201. A photoresist layer is spinned on covering a portion of the cap layer 206. Using the photoresist layer as a mask, the cap layer 206, the emitter 205, the base 204 and the collector 203 are etched to expose the sub-collector 202. A device isolation process is conducted by performing photolithographic and etching processes so that a portion of the sub-collector 202 is etched away and a portion of the semi-insulating substrate 201 is exposed.

As shown in FIG. 2B, lift-off technique is applied to form an emitter metal layer 210 over the cap layer 206, a collector metal layer 211 over the sub-collector 202 and a contact pad metal layer 212 over the substrate 201. An annealing operation is next conducted.

As shown in FIG. 2C, the cap layer 206 is etched to expose the emitter 205. At this stage, if the emitter 205 is too thick, thickness of the emitter 205 must also be reduced.

As shown in FIG. 2D, a patterned photoresist layer is formed over the emitter 205. Using the photoresist layer as a mask, the emitter 205 is etched to form a contact hole. Lift-off technique is again applied to form a base metal layer 213 over the exposed base 204.

As shown in FIG. 2E, an insulation layer 214 such as a polyimide layer is deposited over the semi-insulating substrate 201. A patterned photoresist layer is formed over the insulation layer 214. Using the patterned photoresist layer as a mask, contact holes 215 are formed over the collector metal layer 211, the base metal layer 213 and the emitter metal layer 210 respectively.

Finally, as shown in FIG. 2F, patterned metallic layers 216 are formed to connect the respective electrodes of the hetero-junction bipolar transistor to large area contact pads 212 through contact holes 215.

Related hetero-junction bipolar transistor techniques can be found in U.S. Pat. No. 5,312,765, U.S. Pat. No. 5,725,786, U.S. Pat. No. 5,798,277, U.S. Pat. No. 5,840,612 and U.S. Pat. No. 6,031,255. Although these patents all use special techniques targeting specific application areas, their fabrication often involves complicated steps.

The aforementioned description shows that the fabrication of large surface area hetero-junction bipolar transistor is relatively simple. However, device parameters at high current density are difficult to measure and a reliability test is difficult to perform. On the other hand, although device parameters at high current density can be easily measured and a reliability test can be easily performed for a small area hetero-junction bipolar transistor, small area hetero-junction bipolar transistors are difficult to manufacture.

### SUMMARY OF THE INVENTION

Accordingly, one object of the present invention is to provide a simplified method of forming a small area hetero-junction bipolar transistor compatible with the method of forming a large area hetero-junction bipolar transistor. By performing one more masking and etching step to form a metal bridge, the device region and the large area contact pad region are isolated so that a small area hetero-junction bipolar transistor is formed. Hence, both large area and small area hetero-junction bipolar transistors are fabricated at the same time in a single process.

A second object of the invention is to provide a method of preventing breakage of the metal bridge so that the yield of a hetero-junction bipolar transistor is increased.

A third object of the invention is to provide a simplified method of forming the metal bridge in a small area hetero-junction bipolar transistor for high frequency applications.

A fourth object of the invention is to provide a method of forming the metal bridge capable of monitoring the parameters for growing an epitaxial layer by metallic chemical vapor deposition so that the parameters can be varied to obtain a high current gain hetero-junction bipolar transistor.

A fifth object of the invention is to provide a simplified double crystal lattice X-ray diffraction measurement for rapidly adjusting the epitaxial growth parameters in the growth of the epitaxial layer in a hetero-junction bipolar transistor.

To achieve these and other advantages and in accordance with the purpose of the invention, as embodied and broadly described herein, the invention provides a method for forming a metal bridge of a hetero-junction bipolar transistor. The method includes etching away a portion of the semiconductor layers under a metallic layer so that the device region and the contact pad region on the semiconductor substrate are isolated from each other. The invention not only can produce small area hetero-junction bipolar transistors with ease, the invention can also fabricate large area and small area hetero-junction bipolar transistors at the same time. By clearing away contact pad capacitance, hetero-junction bipolar transistors suitable for high frequency applications can be manufactured with a few simple steps. In addition, the metal bridge of this invention can be fabricated on a semiconductor layer, which can serve as a support for increasing the strength of the metal bridge. Furthermore, utilizing the relationship between the intensity of diffraction from of a double crystal X-ray diffraction analyzer and the current gain of a hetero-junction bipolar transistor, high performance hetero-junction bipolar transistors can be produced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A through 1D are schematic cross-sectional views showing the progression of steps for producing a conventional large area hetero-junction bipolar transistor;

FIGS. 2A through 2F are schematic cross-sectional views showing the progression of steps for producing a conventional small area hetero-junction bipolar transistor;

FIGS. 3A through 3C are schematic cross-sectional views showing the progression of steps for producing a small area hetero-junction bipolar transistor according to this invention;

FIG. 4A is a top view showing the application of a metal bridge technique in an emitter metal layer;

FIG. 4B is a top view showing the application of a metal bridge technique in an emitter metal layer and a base metal layer;

FIG. 5A is a diagram showing the positions of a few bridge supports for preventing the collapse of a metal bridge;

FIG. 5B is a photograph taken from the top by a scanning electron microscope showing the bridge support structures of a metal bridge;

FIG. 5C is a photograph taken from the side by a scanning electron microscope showing the bridge support structures of a metal bridge;

FIGS. 6A through 6C are schematic cross-sectional views showing the progression of steps for forming a metal bridge with a supporting layer in the fabrication of a hetero-junction bipolar transistor;

FIGS. 7A through 7C are schematic perspective views showing the progression of steps for forming a high frequency hetero-junction bipolar transistor using a metal bridge technique;

FIG. 7D is a magnified view of the metal bridge shown in FIG. 7C;

FIG. 8A is a double crystal X-ray diffraction spectrum of an epitaxial layer grown with inferior growth parameters;

FIG. 8B is a double crystal X-ray diffraction spectrum of an epitaxial layer grown with superior growth parameter; and

FIGS. 9A and 9B are graphs showing the forward bias characteristics of the collector current and the base current of a hetero-junction bipolar transistor.

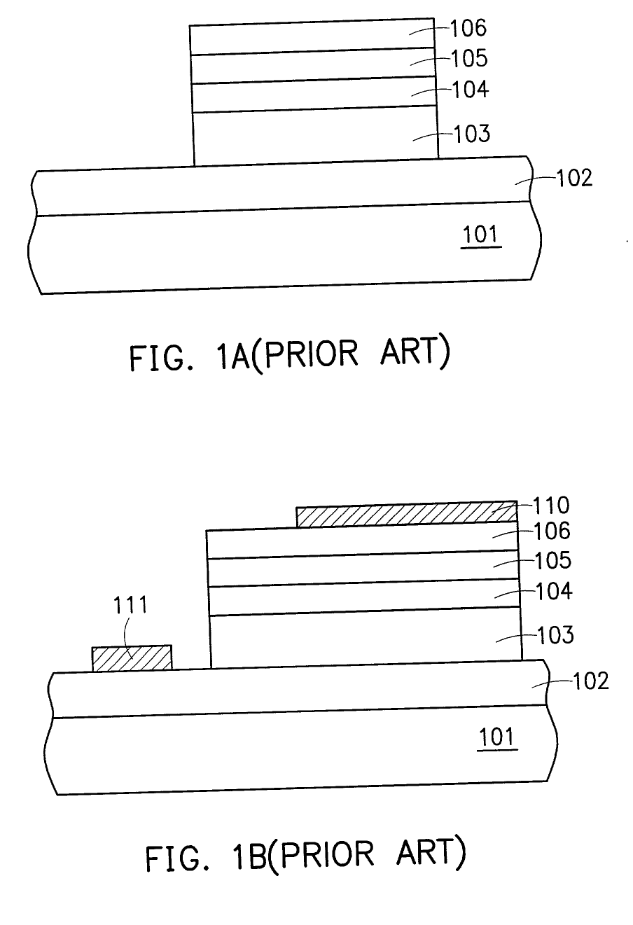

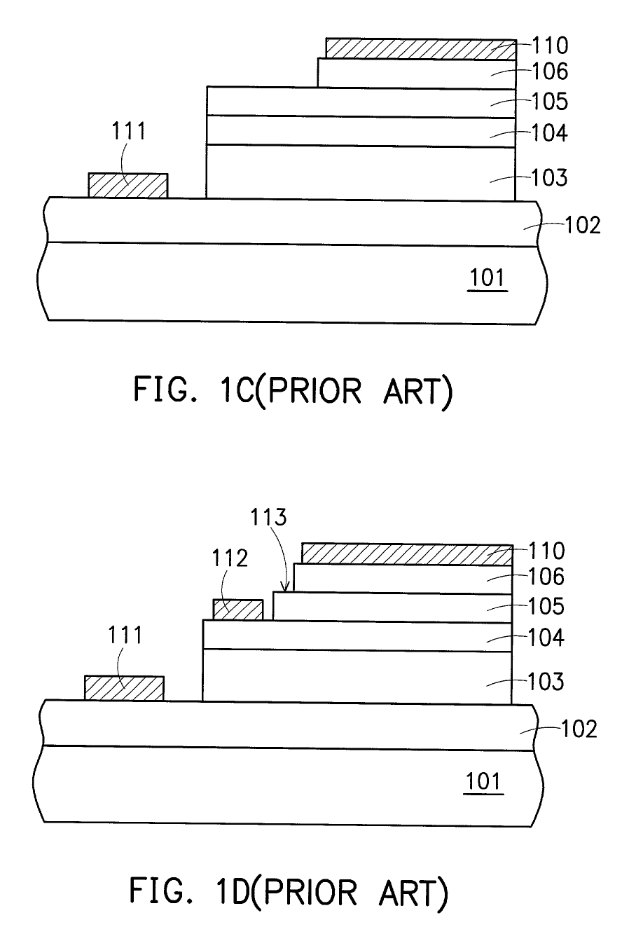

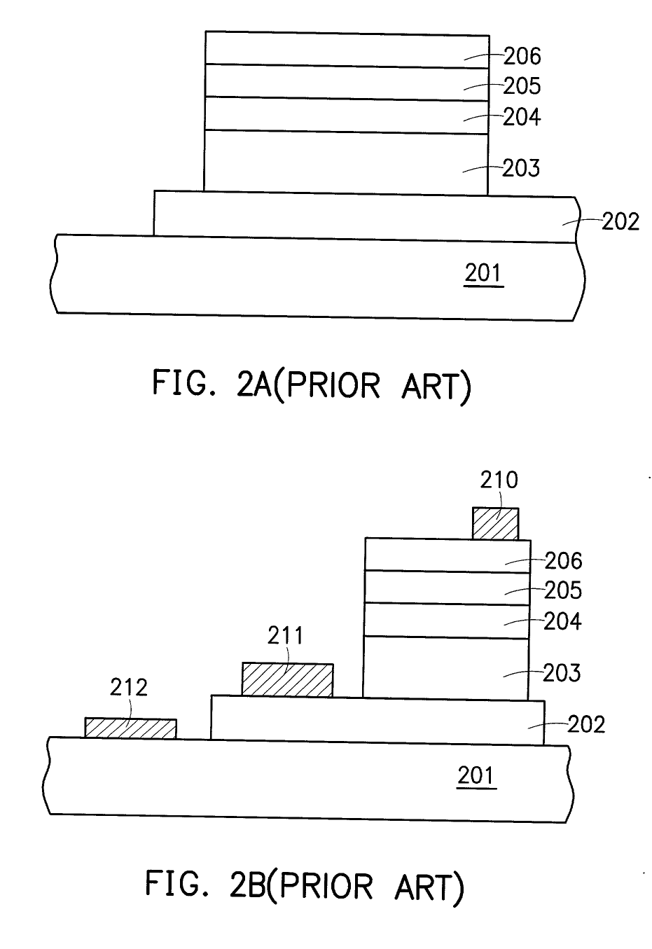

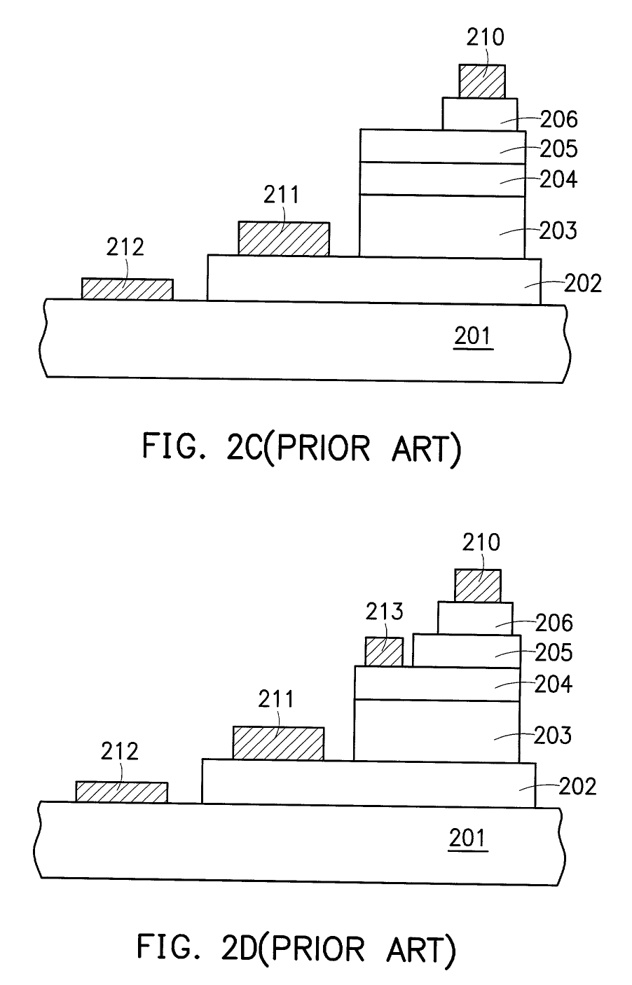

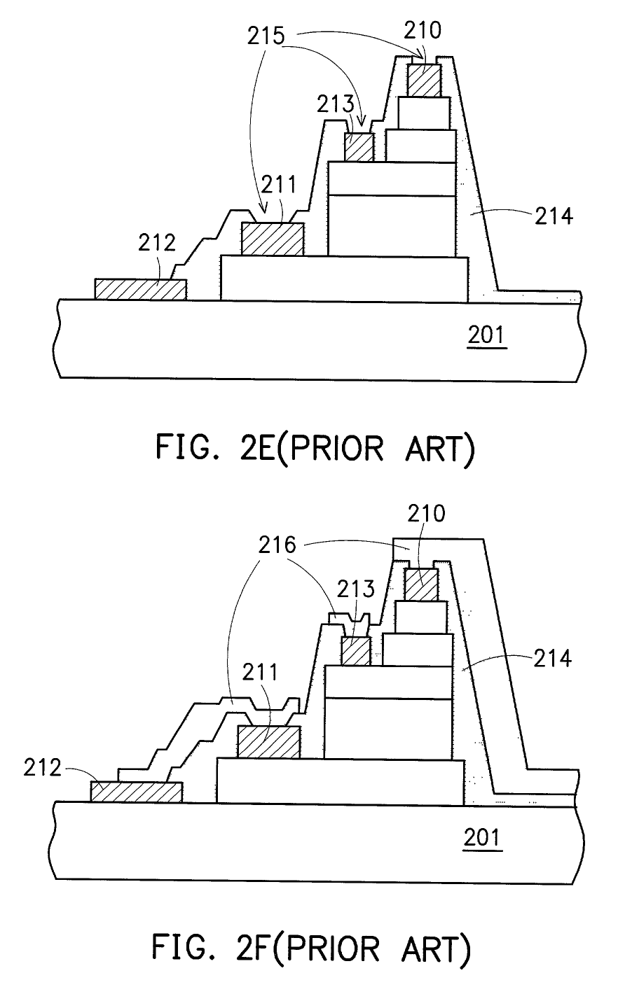

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

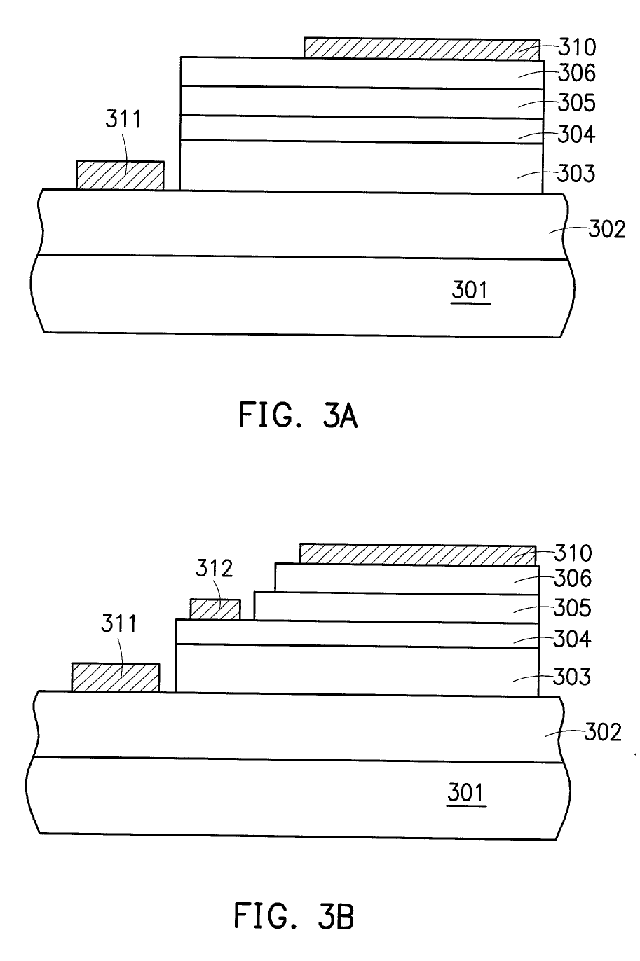

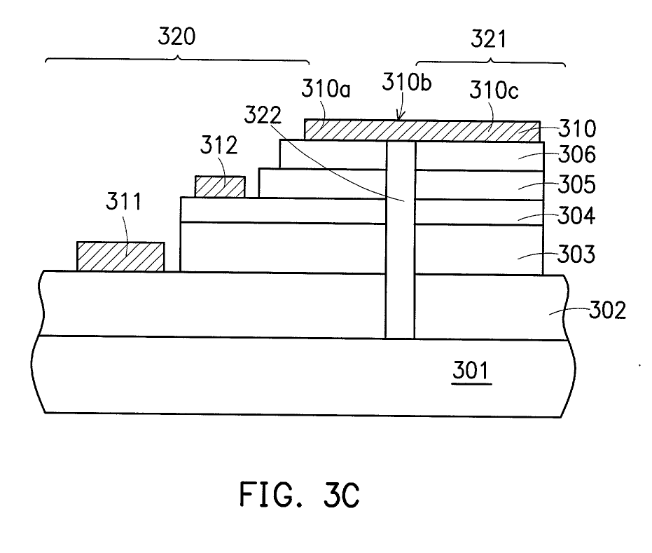

FIGS. 3A through 3C are schematic cross-sectional views showing the progression of steps for producing a small area hetero-junction bipolar transistor according to this invention. As shown in FIG. 3A, a semi-insulating substrate 301 is provided. A sub-collector 302, a collector 303, a base 304, an emitter 305 and a cap layer 306 are sequentially formed over the semi-insulating substrate 301. A portion of the collector 303, the base 304, the emitter 305 and the cap layer 306 are removed to expose a portion of the sub-collector 302. Lift-off technique is applied to form an emitter metal layer 310 and a collector metal layer 311.

As shown in FIG. 3B, a portion of the cap layer 306 is etched until the emitter 305 is exposed. If the emitter 305 is too thick, a portion of emitter 305 is removed so that the exposed emitter 305 has a thickness smaller than 700 Å. A base contact hole is formed above the emitter 305. The exposed emitter 305 under the contact hole is etched to expose the base 304. Lift-off technique is used to form a base metal layer 312 over the base 304.

As shown in FIG. 3C, the position for forming a metal bridge 310b is defined. For example, a patterned photoresist layer is formed over a device region 320 and a contact pad region 321. Using the patterned photoresist layer as a mask, a portion of the cap layer 306, the emitter 305, the base 304, the collector 303 and the sub-collector 302 are sequentially removed to form a hollow section 322. This hollow section 322 not only divides the semiconductor layers into the device region 320 and the contact pad region 321, but also reduces the contact area of the emitter 305 and the base 304 in the device region. Meanwhile, sufficiently large contact pads for the application of probing pins are retained. Hence, there is no need to perform the additional steps of depositing an insulating layer (such as polyimide) and forming contact holes, so that a small area hetero-junction bipolar transistor can be easily fabricated. Finally, the sub-collectors 302 of individual devices are electrically isolated. In FIG. 3C, the emitter metal layer 310 can be divided into a metallic layer 310a above the device region, a metal bridge 310b and a contact pad region 310c. Signals to be measured by an analyzer can be obtained from the large area contact pad 310c via the metal bridge 310b into the metallic layer 310a above the device region. In this way, a small area hetero-junction bipolar transistor can be fabricated with ease while the high-density density parameters of the hetero-junction bipolar transistor can be measured through the large area contact pad 310c. The method of this invention can also be applied to perform a measurement of the parameters of a hetero-junction bipolar transistor in a reliability testing.

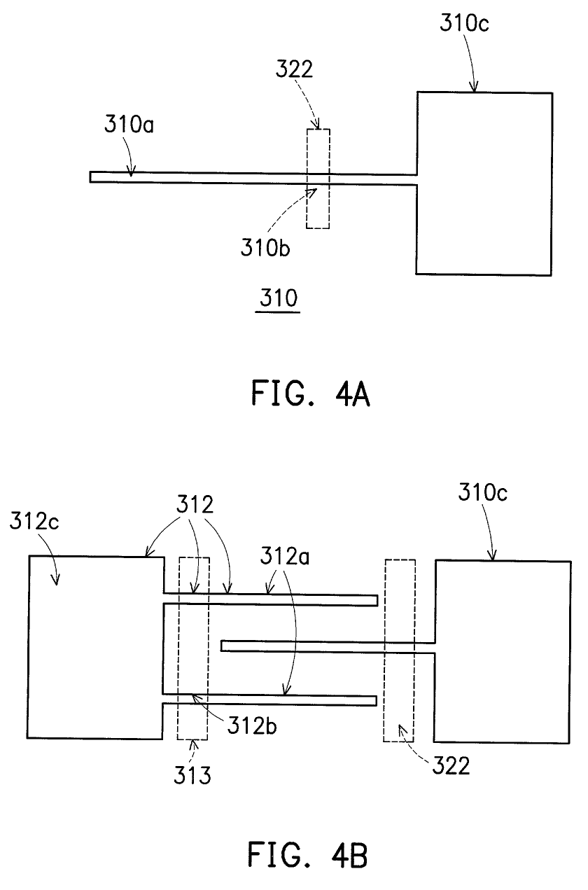

FIG. 4A is a top view showing the application of the metal bridge technique in an emitter metal structure. As shown in FIG. 4A, the emitter metal layer structure 310 includes an emitter metal layer 310a above the device region, a metal bridge 310b and a contact pad 310c. The region underneath the metal bridge 310b is the uncovered portion when etched using the photoresist layer as a mask, thereby forming a hollow section 322. Since an etchant having a higher etching rate for the semiconductor material under the metal bridge 310b is used, the hollow section 322 is capable of electrically isolating the device region from the contact pad region. The metal bridge 310b is retained to serve as a link between the small area device metal layer 310a and the large area contact pad portion of the metal layer 310c.

FIG. 4B is a top view showing the application of the metal bridge technique in an emitter metal layer and a base metal layer. When a metal bridge technique is applied to a base metal layer, the junction area between the base and the emitter can be reduced. The emitter metal layer structure 310 is identical to the emitter metal structure 310 in FIG. 4A. There is a hollow section 322 underneath the emitter metal layer 310. The base metal layer 312 has a similar structure and there is a hollow section 313 underneath the base metal layer 312. The base metal structure 312 includes a base metal layer 312a above the device region, a metal bridge 312b and a base metal contact pad 312c. The structure 310 can reduce the junction area between the emitter and the base while the structure 312 can reduce the junction area between the base and the collector. Note that the emitter metal layer 310 and the base metal layer 312 are on different planes. In fact, the emitter metal layer 310 is at a higher level than the base metal layer 312.

Another advantage of this invention is the capacity to produce both large area and small area hetero-junction bipolar transistors in the same processing steps. This is because the method of forming the large area and the small area hetero-junction bipolar transistor are compatible. Hence, only an additional metal bridge step, beyond what is used for a conventional large area hetero-junction bipolar transistor, is required in the fabrication of this invention (refer to FIG. 3C). In other words, large area and small area hetero-junction bipolar transistors can be produced concurrently using simple processing steps. The quality of the epitaxial layer can be further analyzed. The large area hetero-junction bipolar transistor permits the lowering of perimeter/area ratio. Ultimately, edge effect can be reduced and the quality of the epitaxial layer can be accurately determined. As for the small area hetero-junction bipolar transistor, high current density electrical parameters of the device can be measured for further analysis and a reliability test can be performed.

In a second embodiment of this invention, a method of strengthening the metal bridge is introduced. The metal bridge portion described in the fabrication process must not be too long or the metal bridge may collapse. Length of a metal bridge is normally designed according to the physical strength of the metal used and thickness of the metal bridge. Hence, two principle methods for preventing the collapse of the metal bridge are proposed here so that production yield may increase.

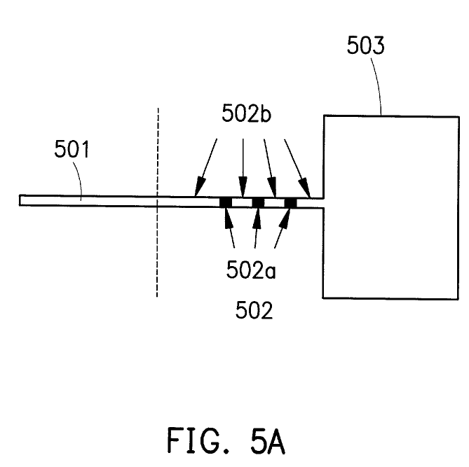

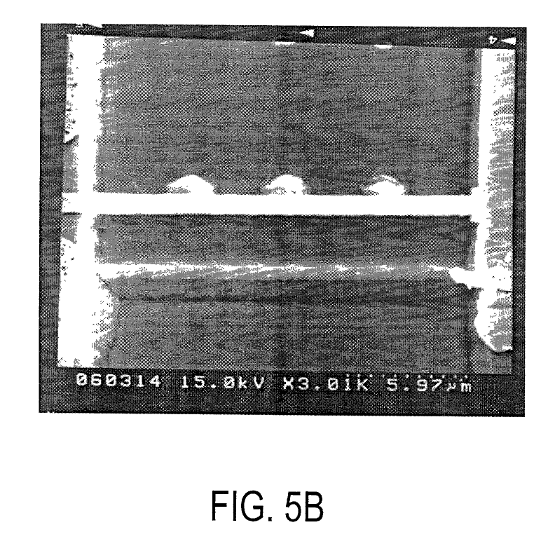

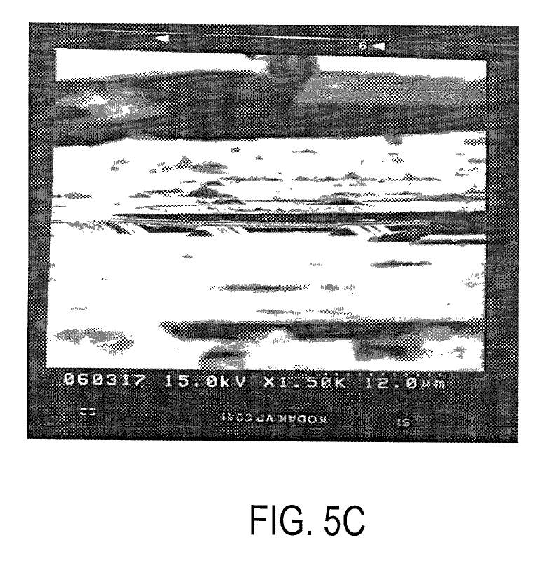

The first method of preventing collapse of the metal bridge is to insert supports under the bridge. If, for some reason, the contact pad region is far away from the device region, leading to a long metal bridge, the addition of supports are ideal for reinforcing the bridge. FIG. 5A is a diagram showing the positions of a few bridge supports for preventing the collapse of a metal bridge. In general, the emitter metal structure or base metal structure can be subdivided into a device region 501, a metal bridge 502 and a contact pad region 503. The metal bridge 502 includes a plurality of bridge supports 502a The bridge supports 502a are formed, for example, by covering those positions for forming supports with photoresist layer. Using the photoresist layer as a mask, the semiconductor material underneath the metal bridge 502 is etched away to form a hollow section 502b while the photoresist covered regions remain to form supports 502a underneath the metal bridge 502.

FIGS. 5B and 5C are photographs taken from the top and the side by a scanning electron microscope showing the bridge support structures of a metal bridge. As shown in FIGS. 5B and 5C, the metal bridge remains intact above the bridge supports showing the feasibility of the invention.

A second method of preventing the collapse of the metal bridge involves the formation of a semiconductor support layer underneath the metal bridge. In the second method, difference in etching rates to a given etchant is utilized to produce the semiconductor support layer that strengthens the metal bridge.

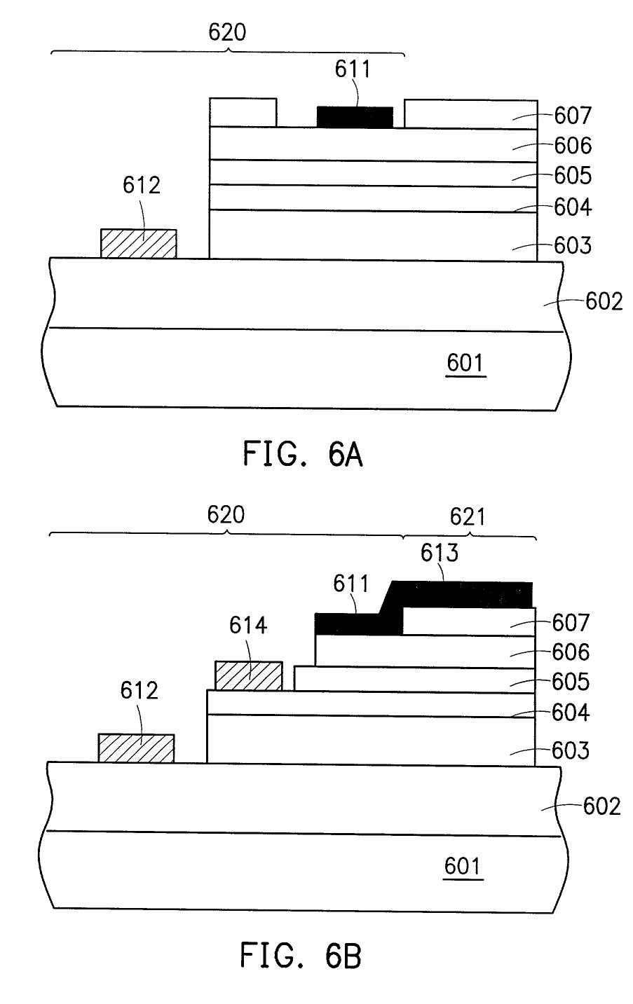

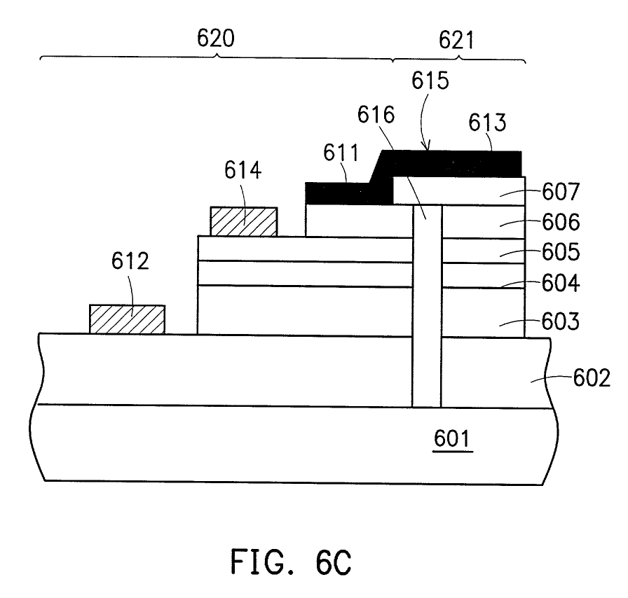

FIGS. 6A through 6C are schematic cross-sectional views showing the progression of steps for forming a metal bridge with a supporting layer in the fabrication of a hetero-junction bipolar transistor. First, as shown in FIG. 6A, a sub-collector 602, a collector 603, a base 604, an emitter 605 and a cap layer 606 are sequentially formed over a semi-insulating substrate 601. The semiconductor layers can be divided into a device region 620 and a contact pad region 621. A semiconductor support layer 607 is formed over the cap layer 606 for supporting the subsequently formed metal bridge. The support layer 607 can be an undoped gallium-indium-phosphide (GaInP) layer, for example. A portion of the collector 603, the base 604, the emitter 605 and the cap layer 606 above the semi-insulating layer 601 are etched until the sub-collector 602 is exposed. A portion of the support layer 607 above the device region 620 is removed. An etchant such as a solution mixture of phosphoric acid and hydrochloric acid may be used in the removal of the support layer 607. The etchant has high etching selectivity so that only the support layer 607 is etched away leaving the sub-collector 602 and the cap layer 606 intact. Lift-off technique is used to form an emitter metal layer 611 over the cap layer 606 and the collector metal layer 612 over the sub-collector 602 in the device region 620.

As shown in FIG. 6B, a lift-off metal layer 613 that links up the emitter metal layer 611 and the contact pad region 621 is formed. Thereafter, an annealing operation is conducted and then the support layer 607 in the device region 620 is removed. A portion of the cap layer 606 is removed to expose a portion of the emitter 605. Similarly, thickness of the extrinsic emitter 605 needs to be controlled below 700 Å to prevent current leak. A patterned photoresist layer is formed over the emitter 605. The exposed emitter 605 under the base contact hole is etched to expose the base 604. Lift-off technique is again applied to form a base metal layer 614 over the base 604.

As shown in FIG. 6C, a portion of the sub-collector 602, the collector 603, the base 604, the emitter 605 and the cap layer 606 between the device region 620 and the contact pad region 621 are etched away to form a hollow section 616. A metal bridge 615 is formed over the hollow section 616. The etchant can be a solution mixture containing ammonia, hydrogen peroxide and water, for example. The etchant has special etching selectivity such that only the sub-collector 602, the collector 603, the base 604, the emitter 605 and the cap layer 606 under the support layer 607 can be removed. The support layer 607 and the lift-off metal layer 613 are resistant to the etching solution. Hence, after the etching step, the metal bridge 615 and the support layer 607 underneath will remain serving as a support preventing the collapse of the metal bridge 615. Finally, the sub-collectors 602 of each device are isolated (not shown) to complete the fabrication.

Due to the support of the support layer 607, breakage of the metal bridge 615 can be safeguarded. Moreover, the undoped gallium-indium-phosphide layer 607 is capable of lowering parasitic capacitance of the contact pads 613 in the contact pad region 621.

In double hetero-junction bipolar transistors (DHBT), the use of support layer is more convenient. This is because there is no need to form a support layer over the cap layer. Metal bridges can be simultaneously formed over the emitter metal layer and the base metal layer. For a double hetero-junction bipolar transistor having emitter/base/collector formed from gallium-indium-phosphide/gallium-arsenide/gallium-phosphide, a solution containing phosphoric acid and hydrochloric acid can be used to etch the gallium-indium-phosphide emitter and collector in the fabrication of the metal bridge. Ultimately, the gallium-arsenide cap layer and base will remain as the support layer for the emitter metal layer and the base metal layer.

In the first embodiment of this invention, the small area hetero-junction bipolar transistor is unsuitable for high frequency applications. This is because the highly doped epitaxial layer underneath the contact pad will lead to a large parasitic capacitance. Parasitic capacitance has an immense effect on a device operating at a high frequency. To reduce the parasitic capacitance under the contact pad, the contact pad can be fabricated on a semi-insulating substrate, and the emitter metal layer connects to the cap layer via a slant section. Continuity of the slant section can be ensured by directional selection and wet etching of the metal during device fabrication.

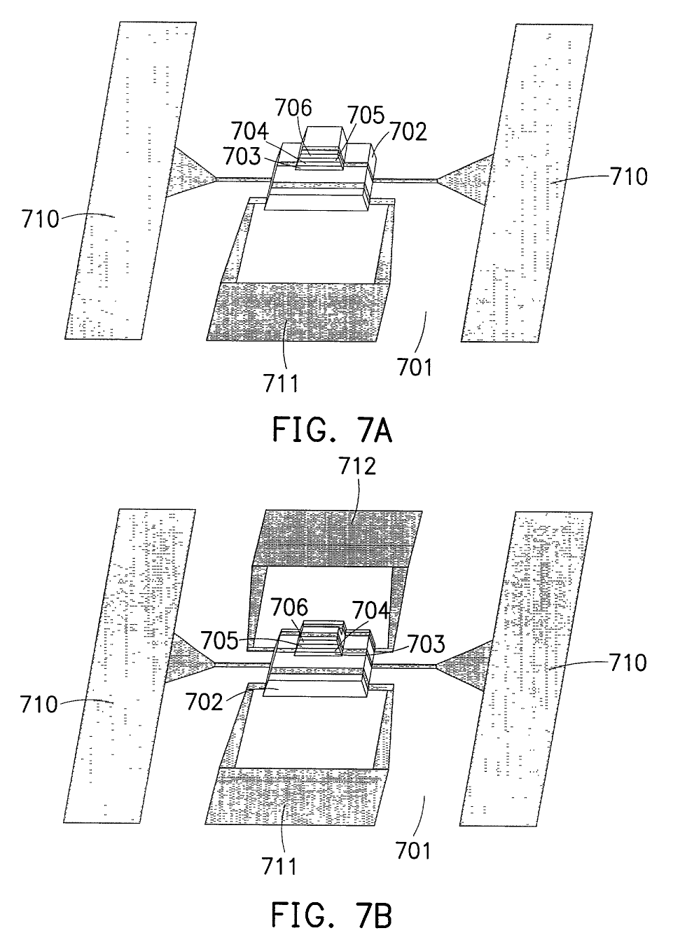

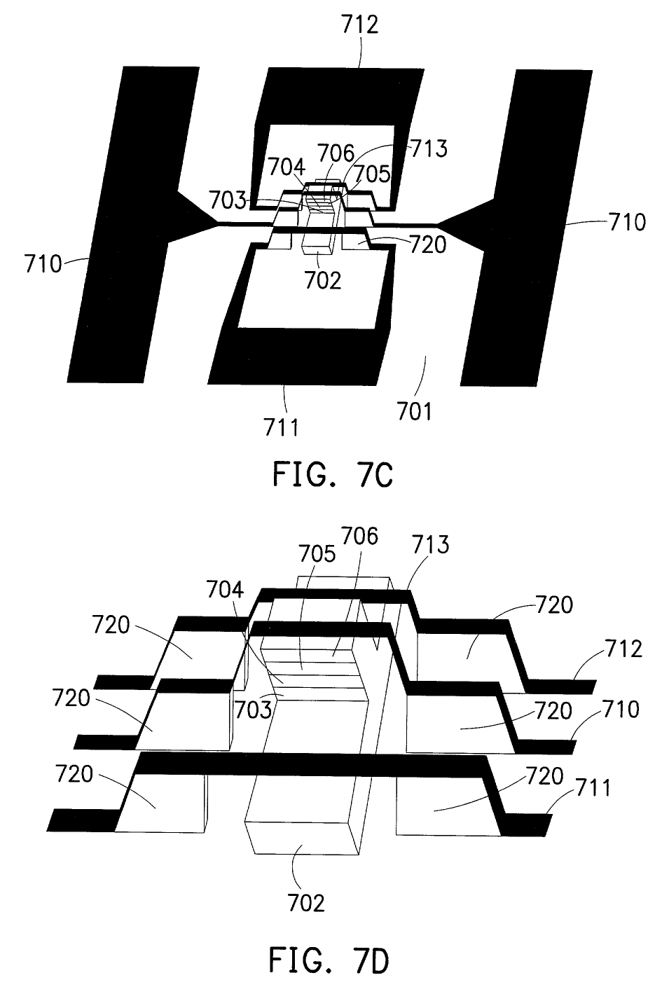

FIGS. 7A through 7C are schematic perspective views showing the progression of steps for forming a high frequency hetero-junction bipolar transistor using a metal bridge technique. As shown in FIG. 7A, a semi-insulating substrate 701 is provided. A sub-collector 702, a collector 703, a base 704, an emitter 705 and a cap layer 706 are sequentially formed over the semi-insulating substrate 701. A platform etching is conducted to expose the sub-collector 702. Another etching is then conducted to expose the semi-insulating substrate 701. Lift-off technique is employed to form an emitter metal layer 710 and a collector metal layer 711. Directionality of the emitter metal layer 710 and the collector metal layer 711 must be considered in the fabrication process so that the emitter metal layer 710 and the collector metal layer 711 can follow a slant section without breakage.

As shown in FIG. 7B, a base contact hole is formed in the emitter 705 and then a lift-off process is applied to form a base metal layer 712. Up to this point, various epitaxial layers are short-circuited through the metal in the slant sections. Furthermore, the emitter metal layer 710, the base metal layer 712 and the collector metal layer 711 are short-circuited through contact with the sub-collector 702.

As shown in FIG. 7C, a metal bridge 713 is formed. The slant section and the device region are isolated and the device region is unaffected by the short-circuiting of the epitaxial layer via the emitter metal layer 710, the base metal layer 712 and the collector metal layer 711. In FIG. 7C, the various layers underneath the metal bridge 713 are mutually separated. Hence, the emitter metal layer 710, the base metal layer 712 and the collector metal layer 711 will not contact the same epitaxial layer (such as the sub-collector layer 702) and lead to short-circuiting.

FIGS. 7D is a magnified view of the metal bridge shown in FIG. 7C. It can be clearly seen in FIG. 7D that the short-circuiting problem is tackled through the formation of the metal bridge 713. Moreover, the metallic layers 710, 711 and 712 are supported by a wall of the semiconductor layer 720 underneath them so that the metal bridges are strengthened.

A fluidic dielectric material such as polyimide can be deposited over the hetero-junction bipolar transistor to serve as a passivation layer. The fluidic property of the dielectric material can be employed to fill the gaps underneath the metal bridge so that the metal bridges are no longer suspended in thin air. Ultimately, the metal bridge will be harder to collapse.

In a fourth embodiment of this invention, both large area and small area hetero-junction bipolar transistors are fabricated concurrently so that properties of the epitaxial layers can be investigated and subsequently improved. In general, the base terminal is highly doped. Hence, the recombination current in the base layer has the biggest effect on the electrical properties of a hetero-junction bipolar transistor. In addition, treatment of the junction between the emitter and the base may also affect the electrical properties of a hetero-junction bipolar transistor. The epitaxial layer structure is formed over a semi-insulating substrate. The epitaxial layer structure includes an n-type highly doped (5×10¹⁸cm⁻³) sub-collector having a thickness of about 5000 Å, an n-type doped (5×10¹⁶cm⁻³) collector having a thickness of about 5000 Å, a p-type highly doped base (above 1×10¹⁹cm⁻³) having a thickness of about 1000 Å, an n-type doped emitter (5×10¹⁷cm⁻³) having a thickness of about 700 Å and an n-type highly doped cap layer (5×10¹⁸cm⁻³) having a thickness of about 2000 Å. The epitaxial layers are formed using an organo-metallic chemical vapor deposition.

To improve the quality of the base layer, temperature, pressure and ratio of V group/III group elements for growing the epitaxial base layer are carefully adjusted. The V group elements include arsine (AsH₃) and the III group includes trimethyl gallium ((CH₃)₃Ga, TMG) or trimethyl indium ((CH₃)₃In, TMIn). A p-type highly doped layer with a thickness much greater than the base layer is formed over the substrate. Thickness of the testing layer is about 1 μm, for example. After the growth of the epitaxial layer, a double crystal X-ray diffraction analyzer is used and a Hall measurement is performed. Thereafter, the same base growth conditions, to grow a hetero-junction bipolar transistor structure are used. Finally, after using the method described in the first embodiment to fabricate large area and small area hetero-junction bipolar transistors concurrently, and to analyze the electrical properties of the device.

In the analysis, the growth temperature is varied from 450° C. to 700° C. The range of temperature to be used is dependent on the type of substrate. For an indium-phosphide (InP) substrate, epitaxial growth temperature is lower, for example, between 450° C. to 600° C. For a gallium-arsenide (GaAs) substrate, a higher epitaxial growth temperature, for example, between 520° C. to 700° C., is required. The ratio between V group/III group elements is usually set between 6 to 40 and the epitaxial growth pressure is generally set between 10 to 100 millibar. According to the above epitaxial growth conditions, a p-type highly doped gallium-arsenide layer with a thickness much greater than the base layer is formed over the substrate. After the growth of the epitaxial layer, a double crystal X-ray diffraction analyzer is used and a Hall measurement is performed. Hetero-junction bipolar transistors are fabricated according to the first embodiment of this invention. Thereafter, direct current (DC) parameters, such as current gain, base sheet resistance, and ideality factor, of the hetero-junction bipolar transistor are measured. A reliability test is also performed. Through the analysis, a clear correlation is found between the intensity obtained from the double crystal X-ray diffraction analyzer and the current gain of the hetero-junction bipolar transistor.

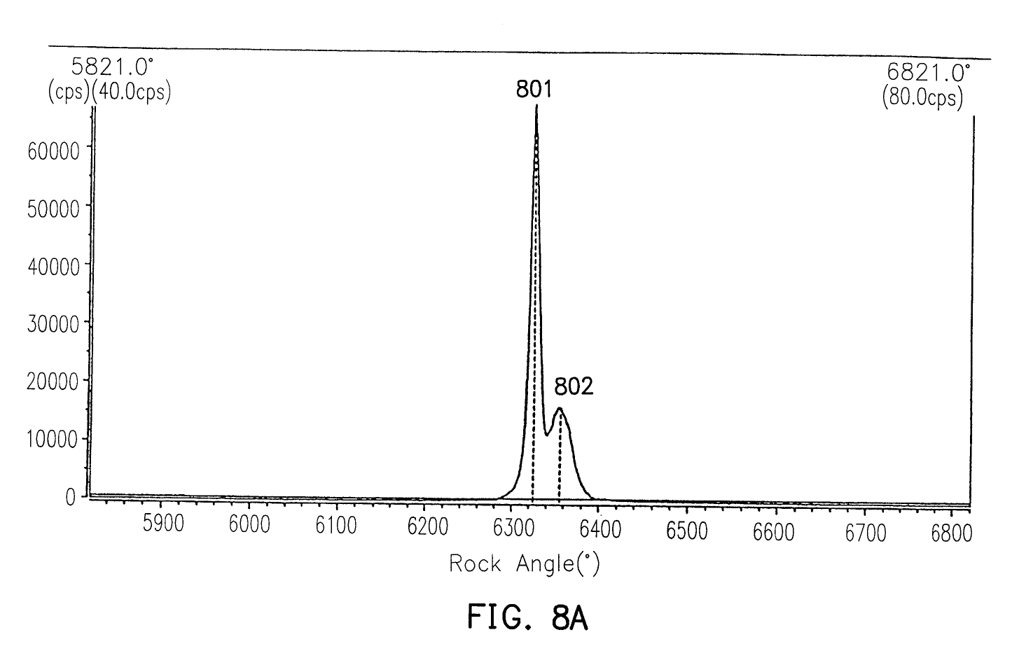

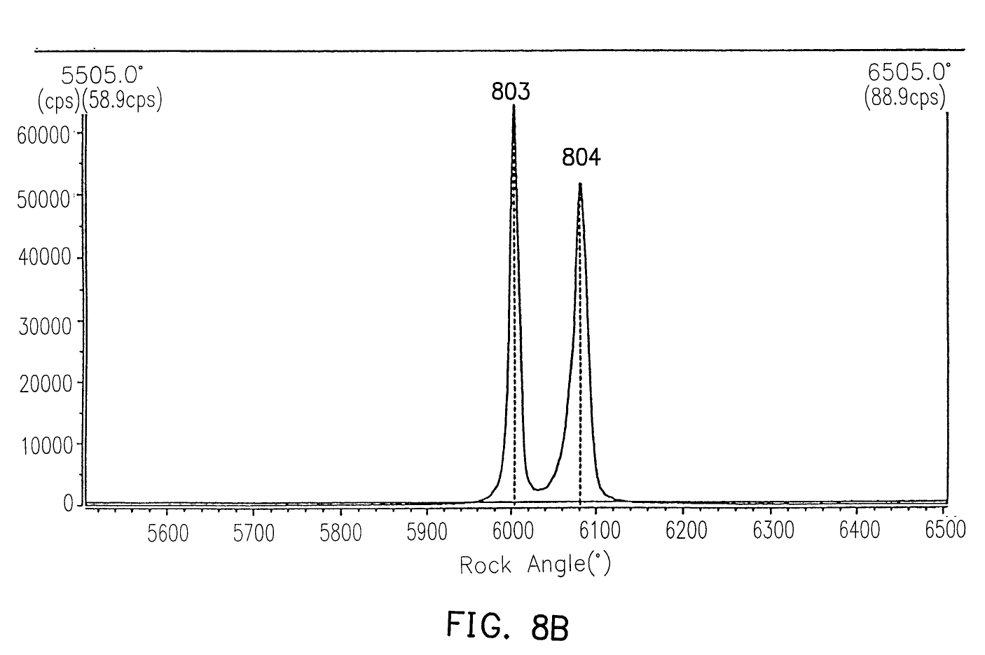

FIG. 8A is a double crystal X-ray diffraction spectrum of an epitaxial layer grown with inferior growth parameters. The peak 801 in the spectrum represents the substrate while the peak 802 represents carbon-doped gallium-arsenide (GaAs). Full width at half medium (FWHM) of the carbon-doped gallium-arsenide peak 802 is 25 and magnitude is only about one-fifth the magnitude of the substrate peak 801.

FIG. 8B is a double crystal X-ray diffraction spectrum of an epitaxial layer grown with superior growth parameter. The peak 803 in the spectrum represents the substrate while the peak 804 represents the carbon-doped gallium-arsenide. The carbon-doped gallium-arsenide peak 804 has a FWHM of 18.8 while the magnitude is about four-fifth the magnitude of the substrate peak 803. In a double crystal X-ray diffraction analysis, the narrower the FWHM and the larger the magnitude, the higher the quality of the epitaxial layer. In FIG. 8B, the carbon-doped gallium-arsenide has a thickness of only 1 μm but is comparable in intensity to the gallium-arsenide substrate with a thickness of about 300 μm. Obviously, the quality of the epitaxial layer after the adjustment of the growth parameters is much better. A subsequent Hall measurement of the two testing specimens reveals the mobility of both are about 90, and shows little difference after the parameter adjustment.

By applying the carbon-doped gallium-arsenide growth parameters in FIGS. 8A and 8B to the epitaxial growth of the base layer of a hetero-junction bipolar transistor and following the steps described in the first embodiment, large area and small area hetero-junction bipolar transistors can be produced concurrently and their parameters measured. For example, a hetero-junction bipolar transistor A is formed using the parameters shown in FIG. 8A while another hetero-junction bipolar transistor B is formed using the parameters shown in FIG. 8B. The transistor A has a current gain 16 and a sheet resistance of 633 Ω/square and hence current gain to sheet resistance ratio is only 0.025. On the other hand, the transistor B has a current gain 10 and a sheet resistance of 260 Ω/square. In other words, the current gain to sheet resistance ratio rises to about 0.15. A sheet resistance of the base terminal must be lowered to obtain better high frequency response. However, an increase in doping concentration or thickness of a base layer often leads to a lowering of current gain. Hence, a comparison of current gain must also incorporate base sheet resistance because current gain and base sheet resistance are positively related. At present, the agreed parameter for assessing the quality of hetero-junction bipolar transistor is the current gain to base sheet resistance ratio. Accordingly, the quality of the epitaxial layer in transistor A and B can be compared using their respective current gain to base sheet resistance ratio. A higher current gain to base sheet resistance ratio for hetero-junction bipolar transistor B shows that an adjustment of the growth parameters such as temperature, pressure, V group/III group element ratio has a positive effect to the ultimate quality. By measuring the intensity of a double crystal X-ray diffraction, various parameters can be adjusted to find the best parameters for forming the carbon-doped gallium-arsenide layer and hence the hetero-junction bipolar transistor. In general, thickness of an epitaxial layer is directly proportional to the intensity obtained from a double crystal X-ray diffraction analyzer. Hence, before comparing diffraction magnitudes, the epitaxial layer must be normalized to 1 μm first. For example, if the epitaxial layer has a thickness of 2 μm, the measured intensity must be divided by 2 to obtain a intensity equivalent to a magnitude having a thickness of 1 μm. Repeated testing has shown that the normalized intensity must have a value at least one-third that of the substrate to form a hetero-junction bipolar transistor with preferable electrical properties.

Aside from the strong relationship between the double crystal X-ray magnitude and FWHM of carbon-doped gallium-arsenide layer and the device properties of a hetero-junction bipolar transistor, the emitter/base interface (E/B interface) also has some critical effects on the properties of the hetero-junction bipolar transistor. Under identical base and emitter growth conditions, the growth of E/B interface is related to the exchange of group V elements. For a hetero-junction bipolar transistor having an indium-gallium-phosphide/gallium-arsenide interface (InGaP/GaAs), the base gallium-arsenide to emitter indium-gallium-phosphide growth involves a transition of group V elements arsenic and phosphorus. In other words, AsH₃ is exchanged with PH₃ during epitaxial growth.

For a hetero-junction bipolar transistor having an indium-phosphide/indiumgallium-arsenide interface (InP/InGaAs), group V element exchange involving AsH₃ and PH₃ still exists. The growth must be paused during the group V elements exchange until the flow stabilizes. However, the suspension period cannot be too long, otherwise other contaminants may adhere to the interface during suspension. The embodiment of this invention has also investigated the interface growth conditions. Under identical growth conditions for base and emitter (without optimizing the growth conditions of the base), an investigation of the effects on the final hetero-junction bipolar transistor structure with respect to four different suspension periods have been conducted. The suspension periods are 10 minutes, 20 seconds, 10 seconds and 5 seconds and the corresponding current gains are 4, 14, 23 and 16 respectively. All of them have a base sheet resistance of 200 Ohms/square. Evidently, there is a definite relationship between the suspension period and device properties. According to gathered data, too long or too short a suspension can have adverse effect on device properties. In general, the suspension period should fall between 1˜20 seconds depending on the epitaxial growth system and cleanliness of the system.

Finally, the optimal growth conditions for forming the base and the optimal interface treatment conditions for forming the emitter/base junction are applied together to produce a hetero-junction bipolar transistor.

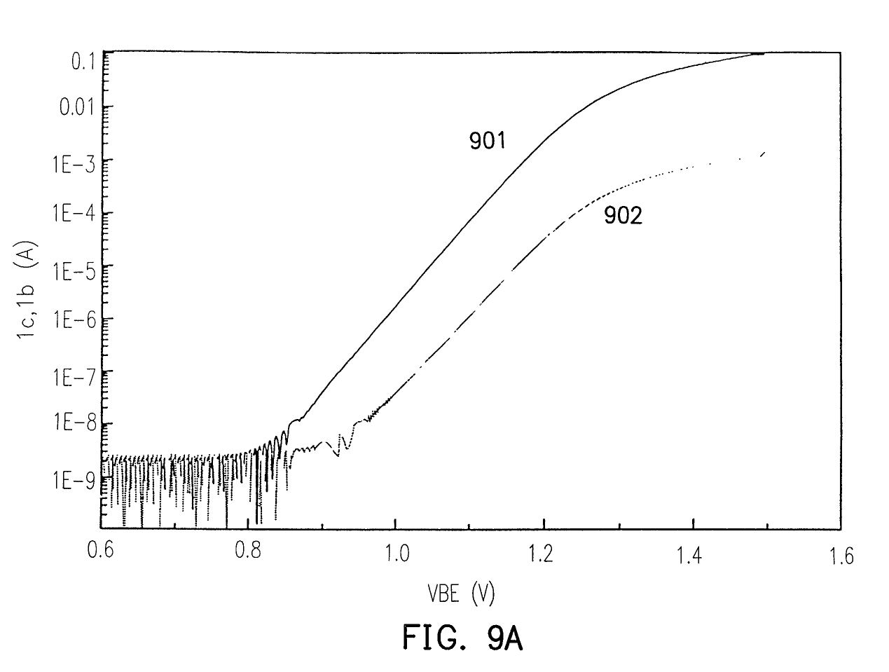

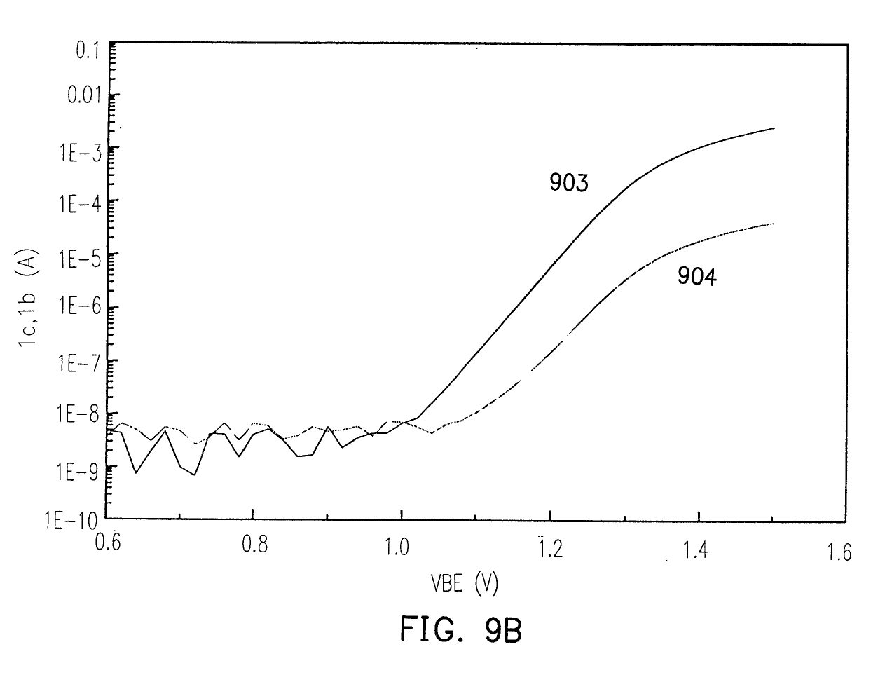

FIGS. 9A and 9B are graphs showing the forward bias characteristics of the collector current and the base current of a hetero-junction bipolar transistor. In FIG. 9A, the emitter area is 50 μm×50 μm. In FIG. 9B, the emitter area is 2 μm×4 μm. A current gain is obtained from the collector current to base current ratio. According to the collector current 901 and the base current 902 in FIG. 9A and the collector current 903 and the base current 904 in FIG. 9B, a current gain as high as 89 is obtained. The measured base sheet resistance for both of them are 200 Ohms/square. The current-gain/base-sheet-resistance ratio increases considerably to about 0.45. FIG. 9B is actually a graph showing forward biasing collector current and base current versus base-emitter voltage for a small area hetero-junction bipolar transistor. The emitter has an area of just 2 μm×4 μm. With such a small emitter area, reliability testing can be conducted. Reliability testing requires a current density of about 25 KA/cm². A supply of collector current of just 2 mA is enough to drive the reliability test as can be verified in FIG. 9B.

In conclusion, the technique of small area device fabrication in this invention can be used to form a metal bridge to improve the operation of hetero-junction bipolar transistors or to simplify production steps. In addition, different organo-metallic chemical vapor deposition (MOCVD) systems often demand different sets of optimal growth parameters for forming hetero-junction bipolar transistors. The invention provides a method of finding the optimal growth parameters using a double crystal X-ray diffraction analyzer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of forming a hetero-junction bipolar transistor, comprising the steps of:
providing a substrate;
sequentially forming a first type dopants doped sub-collector, a first type dopant doped collector, a second type dopant doped base, a first type dopant doped emitter and a first type dopant doped cap layer over the substrate;
patterning out a device region and an isolation region on the substrate;
forming an emitter metal layer, a base metal layer and a collector metal layer over the cap layer, the base and the sub-collector respectively; and
forming a metal bridge pattern over the emitter metal layer, the base metal layer and the collector metal layer, and removing the cap layer, the emitter, the base, the collector and the sub-collector underneath the metal bridge to form a metal bridge.

2. The method of claim 1, wherein the first type dopant is an n-type dopant while the second type dopant is a p-type dopant.

3. The method of claim 1, wherein the first type dopant is a p-type dopant while the second type dopant is an n-type dopant.

4. The method of claim 1, wherein the emitter metal layer, the base metal layer and the collector metal layer can each be subdivided into a device region, a contact pad region and a metal bridge.

5. The method of claim 1, wherein the step of forming the metal bridge further includes erecting a plurality of bridge supports underneath the metal bridge.

6. The method of claim 1, wherein the metal bridge has at least one cylindrical column underneath for supporting the metal bridge.

7. The method of claim 1, wherein the metal bridge has a supporting layer or at least a cylindrical column underneath for supporting the metal bridge.

8. The method of claim 1, wherein the step of forming the metal bridge further includes filling the space underneath the metal bridge with dielectric materials to provide a support to the metal bridge.

9. The method of claim 4, wherein the contact pad regions of the emitter metal layer, the base metal layer and the collector metal layer are above the substrate and are connected to the device region via the metal bridge.

10. The method of claim 1, wherein the method can be applied to form a single hetero-junction bipolar transistor whose collector and base are formed using identical material as well as to form a double hetero-junction bipolar transistor whose collector and base are formed using different materials.

11. A method of forming hetero-junction bipolar transistors by organo-metallic chemical vapor deposition, comprising the steps of:
providing a substrate;
sequentially forming a first type dopants doped sub-collector, a first type dopant doped collector, a second type dopant doped base, a first type dopant doped emitter and a first type dopant doped cap layer over the substrate by performing organo-metallic chemical vapor deposition;
controlling the growth parameters for forming the second type dopant highly doped base so that the base bulk recombination current of the hetero-junction bipolar transistor is reduced; and
controlling the growth parameters for forming the emitter/base interface so that the recombination current in the space charge region is reduced.

12. The method of claim 11, wherein the current gain to base sheet resistance ratio of the hetero-junction bipolar transistor is greater than 0.15.

13. The method of claim 11, wherein the substrate material includes gallium-arsenic or indium-phosphorus.

14. The method of claim 11, wherein the first type dopants includes n-type dopants such as silicon, selenium or tellurium.

15. The method of claim 11, wherein the second type dopants includes p-type dopants such as carbon.

16. The method of claim 11, wherein the growth parameters for forming the second type dopant highly doped base includes a growth temperature between 450° C. to 700° C., an equivalent flow ratio of V group/III group elements of between 6 to 40 and a pressure of between 10 to 100 millibars.

17. The method of claim 11, wherein the adjustment of growth parameters for forming the second type dopant highly doped base includes:
growing a layer of second type dopant highly doped base material epitaxially over the substrate; and
measuring the intensity of diffraction of the substrate and the highly doped base material layer using a double crystal X-ray diffraction analyzer and normalizing the measured epitaxial layer diffraction intensity to an equivalent intensity for a thickness of 1 μm, and the equivalent intensity is at least one-third of the intensity of the substrate.

18. The method of claim 16, wherein the V group sources includes arsine (AsH₃), the III group sources includes trimethyl gallium ((CH₃)₃Ga, TMG) or trimethyl indium ((CH₃)₃In, TMIn).

19. The method of claim 11, wherein the growth parameters for forming emitter/base interface include a growth suspension period between the base and the emitter.

20. The method of claim 19, wherein the growth suspension period between the base and the emitter ranges from about 1 second to 20 seconds.

21. A hetero-junction bipolar transistor structure, comprising:
a substrate that includes a device region and an isolation region, wherein the device region has a sub-collector, a collector, a base, an emitter and a cap layer; and
an emitter metal layer, a base metal layer and a collector metal layer over the cap layer, the base and the sub-collector respectively, wherein the emitter metal layer, the base metal layer and the collector metal layer each includes a device region, a contact pad region and a metal bridge, and the metal bridge has a support layer underneath.

22. The structure of claim 21, wherein the metal bridge further includes at least one cylindrical column underneath for supporting the metal bridge.

23. The structure of claim 21, wherein the space underneath the metal bridge is filled up with a dielectric material for providing additional support for the metal bridge.

24. The structure of claim 21, wherein the emitter metal layer, the base metal layer and the collector metal layer in the contact pad region can be placed above the substrate and are connected to the device region via the metal bridge.

25. The structure of claim 21, wherein the structure is suitable for forming a single hetero-junction bipolar transistor whose collector and base are formed using identical material as well as a double hetero-junction bipolar transistor whose collector and base are formed using different materials.
